(19) United States
(12) Patent Application Publication
(10) Pub. No.: US 2023/0201871 A1
(43) Pub. Date: Jun. 29, 2023

(54) METHOD FOR ACTIVATING AN EXPOSED LAYER

(71) Applicant: COMMISSARIAT A L'ENERGIE ATOMIQUE ET AUX ENERGIES ALTERNATIVES, Paris (FR)

(72) Inventors: Pierre BRIANCEAU, Grenoble Cedex 09 (FR); Nicolas POSSEME, Grenoble Cedex 09 (FR); Elisa VERMANDE, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/068,759

(22) Filed: Dec. 20, 2022

(30) Foreign Application Priority Data
Dec. 29, 2021 (FR) 21 14613

(51) Int. Cl. B05D 3/14; B05D 1/00

(52) U.S. Cl. CPC B05D 3/145; B05D 1/62; B05D 2203/30

(57) ABSTRACT

A method for activating an exposed layer of a structure including a provision of a structure including an exposed layer, and before or after the provision of the structure, a deposition in the reaction chamber of a layer based on a material of chemical formula CₓH_{y}F_{z}, at least x and z being non-zero. The method further includes a treatment, in the presence of the structure, of the layer based on a material of chemical formula CₓH_{y}F_{z} by an activation plasma based on at least one from among oxygen and nitrogen. The treatment by the activation plasma is configured to consume at least partially the layer based on the material of chemical formula CₓH_{y}F_{z} so as to activate the exposed layer of the structure.

### TECHNICAL FIELD

The present invention relates to the field of methods for activating a surface of a structure such as a substrate. Generally, the field of microelectronic devices is targeted.

It has a particularly advantageous application in the field of direct bonding of substrates.

### STATE OF THE ART

It is generally known to assemble several substrates by direct bonding for manufacturing microelectronic devices. For this, there are solutions implementing an activation plasma making it possible to improve the bonding energy between the assembled substrates. In these solutions, the exposed layer of a substrate is typically treated by an oxygen- or nitrogen-based activation plasma, prior to assembly. In practice, the bonding energy obtained remains too limited.

The injection of the fluorinated gas, such as carbon tetrafluoride of chemical formula CF₄ or sulphur hexafluoride of chemical formula SF₆ in an oxygen-based activation plasma makes it possible to increase the bonding energy between two substrates assembled following this treatment. This solution has proved to be limited in practice, in particular due to an etching of the exposed layer during the treatment by the activation plasma.

A method comprising the formation of a bonding layer comprising fluorine on the exposed layer of a substrate is known, in particular, from document U.S. Pat. No. 10,434,749 B2, prior to the assembly by direct bonding of the substrate with another substrate. The bonding layer can in particular be formed by the treatment of an exposed layer by an etching plasma comprising CF₄ or SF₆. The bonding layer is activated and finalised to modify its surface chemistry prior to bonding. This solution however remains improvable.

An aim of the present invention is therefore to propose a solution aiming to improve the direct bonding on a substrate, and in particular aiming to limit the etching of the exposed layer.

Other aims, features and advantages of the present invention will appear upon examining the following description and accompanying drawings. It is understood that other advantages can be incorporated.

### SUMMARY

To achieve this aim, according to a first aspect, a method for activating an exposed layer of a structure is provided, comprising:
a provision of a structure comprising an exposed layer in a reactor, preferably a plasma reactor, the reactor comprising a reaction chamber inside which the structure is disposed,
before or after the provision of the structure, a deposition in the reaction chamber of a layer based on a material of chemical formula CₓH_{y}F_{z}, x, y and z being positive integers, at least x and z being non-zero,
a treatment, in the presence of the structure, of the layer based on a material of chemical formula CₓH_{y}F_{z} by an activation plasma based on at least one from among oxygen and nitrogen, the treatment by the activation plasma being configured to consume at least partially, preferably totally, the layer based on the material of chemical formula CₓH_{y}F_{z} so as to activate the exposed layer of the structure.

This method this makes it possible to temporally separate the formation of a fluorinated layer and the activation by the activation plasma. The subsequent bonding is improved by an increase of bonding energy. On the other hand, the consumption of the exposed layer is limited with respect to the solutions implementing an intake of fluorinated gas in the activation plasma.

During the development of the invention, it has been further highlighted that the deposition of a layer of chemical formula CₓH_{y}F_{z} limits, and preferably avoids, the etching of the exposed layer with respect to the current solutions implementing an SF₆- or CF₄-based plasma-enhanced deposition, prior to the activation plasma.

The deposition of a layer of chemical formula CₓH_{y}F_{z}, also called layer CₓH_{y}F_{z}, prior to an activation plasma, is clearly distinguished from the current solutions for the activation of an exposed layer. On the contrary, a person skilled in the art would be dissuaded from depositing species comprising carbon, as carbon is generally considered as to be proscribed to obtain high bonding energies. In the method, during the activation plasma, the carbon of the layer CₓH_{y}F_{z} is removed in the form of gas emission, for example in the form of gas of formula CO, CO₂, or CN. An increase of bonding energy can be obtained while limiting the etching of the layer.

Furthermore, this solution differs from current solutions implementing a CF₄ plasma, which induce an etching of the exposed layer, and do not make it possible to deposit a fluorinated layer on the surface of the exposed layer.

In order to limit the etching of the exposed layer, a person skilled in the art would have rather considered decreasing the concentration of CF₄ or SF₆ added to an etching O₂ plasma, which would reduce the resulting bonding energies. The deposition of a layer of chemical formula CₓH_{y}F_{z} prior to an activation plasma enables a better reproducibility and a time saving.

A second aspect of the invention relates to a method for bonding an exposed layer of a structure with an exposed layer of a distinct substrate, the method comprising:
the activation of the exposed layer of the structure by implementing the method according to the first aspect,
the contact of the exposed layer of the structure with the exposed layer of the distinct substrate.

Preferably, the exposed layer of the structure with the exposed layer of the distinct substrate are assembled by direct bonding. This method has the effects and advantages of the method according to the first aspect. The bonding method makes it possible to obtain an assembly having a bonding interface, between the exposed layer of the structure of the exposed layer of the distinct substrate, improved with respect to the current solutions. The bonding method makes it possible to obtain an assembly having a bonding energy improved with respect to the current solutions.

### BRIEF DESCRIPTION OF THE FIGURES

The aims, objectives, as well as the features and advantages of the invention will emerge best from the detailed description of an embodiment of the latter, which is illustrated by the following accompanying drawings, wherein:

FIG. 1 represents a transverse, cross-sectional view of a structure having an exposed layer, according to an example of an embodiment.

FIG. 2A represents a transverse, cross-sectional view of the reaction chamber of a reactor, during an example of deposition of a layer based on the material of formula CₓH_{y}F_{z} on the exposed layer of the structure according to the example of the embodiment illustrated in FIG. 1.

FIG. 2B represents a transverse, cross-sectional view of the reaction chamber of a reactor, after the deposition of a layer based on the material of chemical formula CₓH_{y}F_{z} on the exposed layer of the structure, according to the example of the embodiment illustrated in FIG. 2A.

FIG. 2C represents a transverse, cross-sectional view of the structure having the exposed layer and the layer based on the material of chemical formula CₓH_{y}F_{z}, according to the example of the embodiment illustrated in FIG. 2B.

FIG. 2D represents a transverse, cross-sectional view of an example of treatment by the activation plasma of the structure according to the example of the embodiment illustrated in FIG. 2C.

FIG. 3A represents a transverse, cross-sectional view of the reaction chamber of a reactor, during the deposition of a layer based on the material of formula CₓH_{y}F_{z}, according to an example of an embodiment.

FIG. 3B represents a transverse, cross-sectional view of the reaction chamber of a reactor, after the deposition of a layer based on the material of chemical formula CₓH_{y}F_{z} on the walls of the reaction chamber, according to the example of the embodiment illustrated in FIG. 3A.

FIG. 3C represents a transverse, cross-sectional view of the reaction chamber of a reactor comprising the structure according to the example of the embodiment illustrated in FIG. 1, during the treatment by the activation plasma, according to the example of the embodiment illustrated in FIG. 3B.

FIG. 4 represents a cross-sectional view of the structure having an activated exposed layer, for example following the examples illustrated by FIGS. 2D or 3C.

FIG. 5 represents a cross-sectional view of an assembly of the structure having an activated exposed layer according to the example illustrated in FIG. 4, with the exposed layer of a distinct substrate.

FIG. 6 schematically represents an example of a reactor which could be used to implement the method according to the invention.

FIG. 7 represents a graph of the bonding energy of an assembly of a structure having an activated exposed layer, with the exposed layer of a distinct substrate, according to several examples of embodiments of the method and comparative examples.

The drawings are given as examples and are not limiting of the invention. They constitute principle schematic representations intended to facilitate the understanding of the invention and are not necessarily to the scale of practical applications. In particular, the thicknesses of the different layers are not representative of reality.

### DETAILED DESCRIPTION

Before starting a detailed review of embodiments of the invention, optional features are stated below, which can optionally be used in association or alternatively.

According to an example, the provision of the structure is made before the deposition of the layer based on a material of chemical formula CₓH_{y}F_{z} in the reaction chamber, the layer based on a material of chemical formula CₓH_{y}F_{z} thus being deposited on the exposed layer of the structure. The fluorine source is thus applied as close as possible to the exposed layer, by deposing the layer CₓH_{y}F_{z} on the exposed layer, while limiting the etching of the exposed layer. A good repeatability of the resulting bonding energy is obtained between different structures treated by the method.

According to an example, the deposition of the layer based on a material of chemical formula CₓH_{y}F_{z} and the treatment by the activation plasma are performed in the same reaction chamber. This makes it possible to simplify the method, to make it cheaper and more easily reproducible.

According to an example, the substrate is left in the reaction chamber between the deposition of the layer based on a material of chemical formula CₓH_{y}F_{z} and the treatment by the activation plasma.

According to an example, the provision of the structure is made after the deposition of the layer based on a material of chemical formula CₓH_{y}F_{z} in the reaction chamber and before the treatment by the activation plasma, the layer based on a material of chemical formula CₓH_{y}F_{z} thus being deposited on walls of the reaction chamber. The deposition of the layer based on a material of chemical formula CₓH_{y}F_{z} and the treatment by the activation plasma are preferably performed in the same reaction chamber. The fluorine source is thus applied in the proximity of the exposed layer, while limiting the etching of the exposed layer. A good reproducibility of the resulting bonding energy is obtained.

According to an example, the treatment by the activation plasma is performed so as to consume at least 90% and preferably all the carbon atoms of the deposited layer based on a material of chemical formula CₓH_{y}F_{z}. According to an example, coming from the treatment by the activation plasma, carbon atoms no longer remain, or at the very least, less than 10% of carbon atoms remain, which were present in the layer based on a material of chemical formula CₓH_{y}F_{z} after the deposition and before the treatment by the activation plasma. Thus, the treatment by the activation plasma makes it possible to remove the carbon element which could impact the bonding energy and/or the properties of the resulting microelectronic device.

According to an example, the treatment by the activation plasma comprises the application of a voltage in the reaction chamber, called self-polarisation voltage, preferably the self-polarisation voltage is non-zero. Thus, the energy of the ions of the activation plasma can be modulated to improve the effectiveness of the ion bombardment on the layer CₓH_{y}F_{z} and therefore the activation of the exposed layer, while limiting the etching of the exposed layer.

According to an example, the absolute value of the self-polarisation voltage is substantially greater than or equal to 100V, preferably substantially greater than or equal to 200V. According to an example, the absolute value of the self-polarisation voltage is substantially less than or equal to 500V. According to an example, the absolute value of the self-polarisation voltage is substantially between 100V and 500V.

According to an example, the treatment by the activation plasma is performed in a reaction chamber of a capacitively coupled plasma reactor.

According to an example, the treatment by the activation plasma is performed in a reaction chamber of an inductively coupled plasma reactor.

According to an example, during the treatment by the activation plasma, a polarisation voltage V_{bias-substrat} is applied to the structure. Thus, the ion bombardment on the layer CₓH_{y}F_{z} and the etching of the exposed layer can be even better controlled and preferably minimised. According to an example, the polarisation voltage V_{bias-substrat} is non-zero. According to an example, the voltage applied to the structure V_{bias-substrat} is chosen such that the absolute value of the self-polarisation voltage is between 100V and 500V.

According to an example, the polarisation voltage V_{bias-substrat} to the structure is pulsed. This makes it possible for a larger parameter window to minimise the etching of the exposed layer while enabling its activation.

According to an example, a polarisation voltage V_{bias-substrat} is applied to the structure independently to the radiofrequency (RF) power of the plasma source Pₛ₋ₚₗₐₛₘₐ.

According to an example, the deposition of the layer based on a material of chemical formula CₓH_{y}F_{z} is a chemical deposition form at least one gaseous precursor. Preferably, the deposition is plasma-enhanced.

According to an example, the at least one gaseous precursor comprises at least carbon, and fluorine elements, the at least one gaseous precursor being different from CF₄.

According to an example, the at least one gaseous precursor is of chemical formula CᵤHᵥF_{w} , u, v and w being positive integers, at least u and w being non-zero, excluding CF₄. According to an example, u, v and w are non-zero positive integers. For example, the at least one gaseous precursor is chosen from among compounds of formula CH₂F₂ and CHF₃ and CH₃F and CᵤF_{w} excluding CF₄, for example C₄F₈, C₄F₆. Indeed, a CF₄ plasma does not make it possible to deposit a fluorinated layer, contrary to a plasma comprising other CᵤF_{w} precursors, such as CF₄F₈, CF₄F₆. A sole CF₄ plasma induces the etching of the exposed layer.

According to an example, during the deposition of the layer based on a material of chemical formula CₓH_{y}F_{z}, the exposed layer is not etched.

According to an example, the activation plasma is nitrogen- and/or oxygen-based.

According to an example, the treatment by the activation plasma comprises an injection of at least one gas in a reaction chamber of a plasma reactor and a formation of the activation plasma from said gas in the reaction chamber. According to an example, the at least one gas comprises dioxygen, dinitrogen, helium, argon or their mixture.

According to an example, the activation plasma has no halogenated species, and in particular fluorine. The activation plasma cannot comprise the injection of a gas comprising halogen elements and in particular, the fluorine element in the reaction chamber. The etching of the exposed layer is therefore minimised, even avoided. Thus, this method is clearly differentiated from known solutions consisting of performing a treatment by an activation plasma with the injection of a gas comprising the fluorine element.

According to an example, the activation plasma is configured to not deposit the layer on the exposed layer and/or the walls of the reaction chamber.

According to an example, the exposed layer is based on a semi-conductor or of a metal or of a metalloid. For example, the exposed layer is based on or made of a metal oxide, for example a semi-conductor oxide, a metal nitride, for example a semi-conductor nitride.

According to an example, the exposed layer is silicon-based. For example, the exposed layer is based on or made of a silicon oxide, a silicon nitride or silicon.

According to an example, after the treatment by the activation plasma, the method can comprise the assembly of the exposed layer of the structure with an exposed layer of a distinct substrate.

According to an example, at least one from among the deposition of the layer based on a material of chemical formula CₓH_{y}F_{z} and the treatment by the activation plasma can be repeated several times. According to an example, at least one from among the deposition and the treatment by the activation plasma can be repeated several times before the assembly of the exposed layer of the structure with an exposed layer of a distinct substrate. Preferably, the deposition of the layer based on a material of chemical formula CₓH_{y}F_{z} and the treatment by the activation plasma form a cycle which could be repeated several times.

By microelectronic device, this means any type of device produced with microelectronic means. These devices comprise, in particular, in addition to devices with a purely electronic purpose, micromechanical or electromechanical devices (MEMS, microelectromechanical systems, NEMS, nanoelectromechanical systems, etc.), as well as optical or optoelectronic devices (MOEMS, micro-opto-electro-mechanical systems, etc.).

It can be a device intended to ensure an electronic, optical, mechanical function, etc. It can also be an intermediary product only intended for the production of another microelectronic device.

By “direct bonding”, this means a bonding without applying adhesive material (of glue or polymer type, in particular) which consists of the contact of relatively smooth surfaces (of a roughness typically less than 5 Å, 10⁻⁹m), for example performed at ambient temperature and in an ambient atmosphere, in order to create an adherence between them.

According to an example, the direct bonding of two substrates means that the bonding is obtained by chemical bonds which are established between the two surfaces put in contact.

The direct bonding can be obtained without requiring the application of a significant pressure on the structure to be assembled. A slight pressure can simply be applied to initiate the bonding. A thermal annealing can further be performed to consolidate the bonding.

By a substrate, a layer, a zone or a portion “based on” a material A, this means a substrate, a layer, a zone or a portion comprising this material A, for example at a rate of at least 50%, and optionally other materials, for example doping elements.

Fully conventionally, a structure based on a metal oxide is a structure made, or comprising a material comprising at least one metal or one metalloid and oxygen. A structure based on a metal nitride is a structure made, or comprising a material comprising at least one metal or a metalloid and nitrogen.

The word “dielectric” qualifies a material of which the electrical conductivity is sufficiently low in the given application to server as an insulator. In the present invention, a dielectric material preferably has a dielectric constant greater than 4.

It is specified that in the scope of the present invention, the term “on”, “surmounts” or their equivalents do not necessarily mean “in contact with”, except “juxtaposed” is otherwise mentioned. For “juxtaposed” layers, or portions, or zones, this means, in this case, that the layers, or portions, or zones are in contact along their main extension plane and disposed on top of one another in the direction of the stack, this direction being perpendicular to the main extension plane. By “in contact”, this means that a thin interface can exist, for example caused by the manufacturing variability.

In the description below, the thicknesses of layer, zone or portion, as well as the depths are generally measured in a vertical direction, parallel to the stacking direction and perpendicular to the main extension plane of the substrate, of the layer, of the sublayer or of the portion.

Moreover, a nitrogen- and/or oxygen-based plasma can be based on a chemistry comprising only nitrogen and/or oxygen or comprising nitrogen and/or oxygen and optionally one or more other species, for example neutral gases (such as helium or argon, for example).

In the present patent application when a gaseous mixture is expressed with percentages, these percentages correspond to fractions of the total flow rate of the gases injected in the reactor. Thus, if a gaseous mixture, for example intended to form a plasma, comprises x % of the gas A, this means that the injection flow rate of the gas A corresponds to x % of the total flow rate of the gases injected in the reactor to form the plasma.

Several embodiments of the invention implementing successive steps of the manufacturing method are described below. Unless explicitly mentioned otherwise, the adjective “successive” does not necessarily imply, even if this is generally preferred, that the steps immediately follow one another, intermediate steps could separate them.

Moreover, the term “step” means the carrying out of some of the method, and can mean a set of substeps.

Moreover, the term “step” does not compulsorily mean that the actions carried out during a step are simultaneous or immediately successive. Certain actions of a first step can, in particular, be followed by actions linked to a different step and other actions of the first step can then be resumed. Thus, the term “step” does not necessarily mean single and inseparable actions over time and in the sequence of phases of the method.

By a parameter that is “substantially equal to/greater than/less than” a given value, this means that this parameter is equal to/greater than/less than the given value, at roughly 10%, even at roughly 5%, of this value. By a parameter that is “substantially between” two given values, this means that this parameter is, as a minimum, equal to the smallest given value, at roughly 10% of this value, and as a maximum, equal to the largest given value, at roughly 10% of this value.

The activation method is now described, in a non-limiting manner, according to several examples of embodiments.

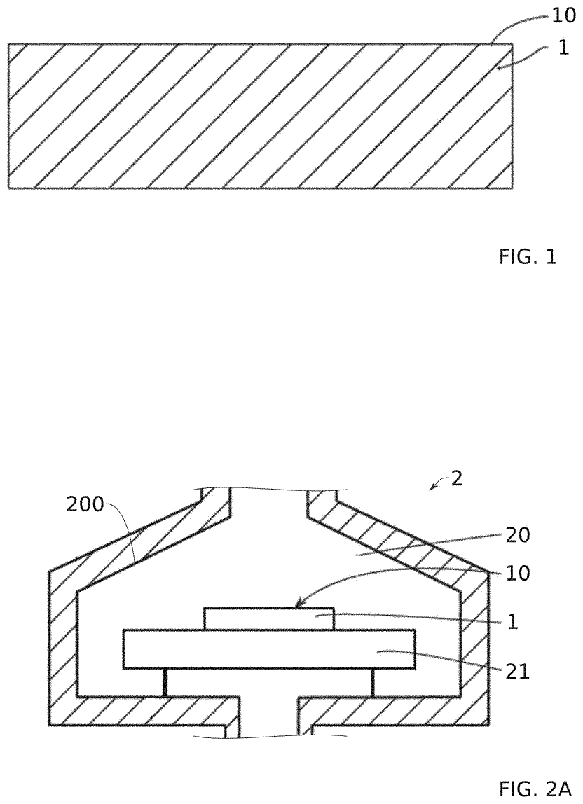

The method is configured to activate the exposed layer 10 of a structure 1, for example illustrated by FIG. 1. Such a structure is, for example, based on a semi-conductor material. In the non-limiting example which will be described in detail, this structure 1 is based on or made of silicon. This structure 1 can be based on or made of a silicon oxide, a silicon nitride or silicon. The structure 1 can be made of so-called “bulk” silicon. Moreover, all the features, steps and technical effects which will be described below are fully applicable to a structure 1, possibly other than a layer, such as a nanostructure, for example three-dimensional, or a plurality of such structures.

The structure 1 can form part of a substrate. This substrate can be formed only of this structure 1. Alternatively, this substrate can comprise a support layer surmounted at least by one such structure 1. The structure has an exposed layer 10, free and exposed to the surrounding species, for example present in the reaction chamber 20 of a reactor 2.

To activate the exposed layer 10, the method mainly comprises three steps: a step of providing the structure, a deposition step and a treatment step. The method comprises the deposition of a fluorinated layer 11 based on a material of chemical formula CₓH_{y}F_{z}, x, y and z being positive integers, at least x and z being non-zero, and an activation plasma 3 configured to consume at least partially, preferably totally, this layer 11 and thus activate the exposed layer 10. The fluorinated layer 11 can therefore be based on a material of chemical formula CₓH_{y}F_{z} or CₓF_{z} when y=0. According to an example, x, y and z are non-zero positive integers. Below, the layer 11 based on a material of chemical formula CₓH_{y}F_{z} is referenced layer CₓH_{y}F_{z} 11 or also layer 11. It is understood that the activation plasma is a step temporally distinct from the step of depositing the layer CₓH_{y}F_{z} 11, these two steps are not simultaneous.

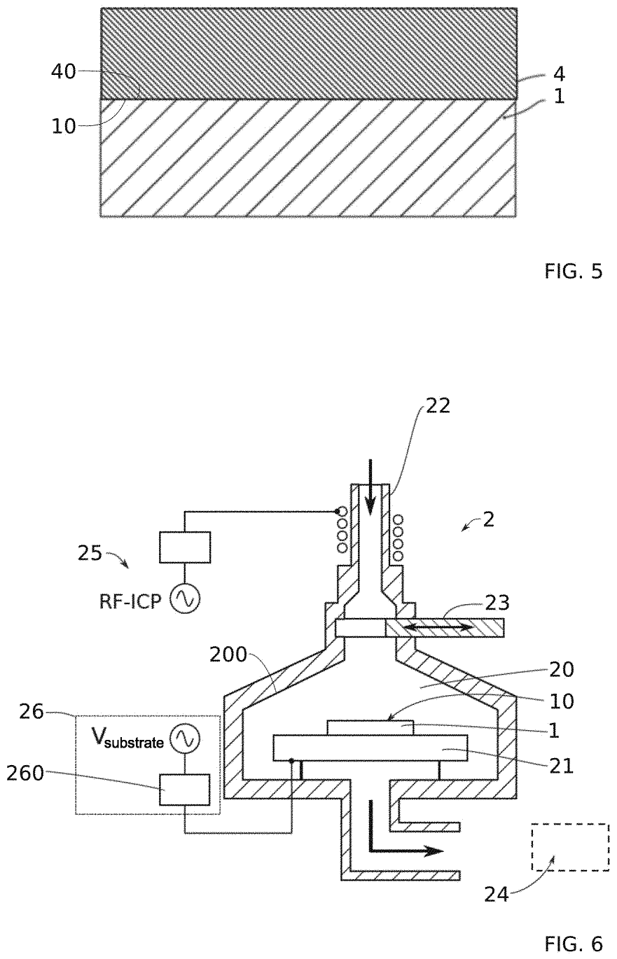

The method is configured to deposit the layer CₓH_{y}F_{z} 11 such that, during the successive treatment by the oxygen- and/or nitrogen-based activation plasma 3, the layer CₓH_{y}F_{z} 11 is located in the proximity of the exposed layer 10. The activation plasma 3 consumes at least partially the layer CₓH_{y}F_{z} 11. The reactions occurring during the consumption of the layer CₓH_{y}F_{z} 11 inducing an activation of the exposed layer 10, for example illustrated in FIG. 4, wherein stars symbolise the activation of the exposed layer 10. The exposed layer 10, once activated, in particular has, on the surface, bonds with fluorine atoms. These surface bonds make it possible to increase the bonding energy during an assembly of the structure with another substrate. The carbon present in the layer CₓH_{y}F_{z} 11 will be removed by the activation plasma 3 in the form of volatile products.

Following the activation of the exposed layer 10, the method can further comprise a step of assembling the structure 1 with a distinct substrate or structure. The exposed layer 10 can be assembled by direct bonding to the exposed layer 40 of the substrate 4 or of the structure 4, as for example illustrated by FIG. 5. The structure 4 can form part of a substrate. This substrate can be formed only of this structure 4. Alternatively, this substrate can comprise a support layer surmounted at least by such a structure 4.

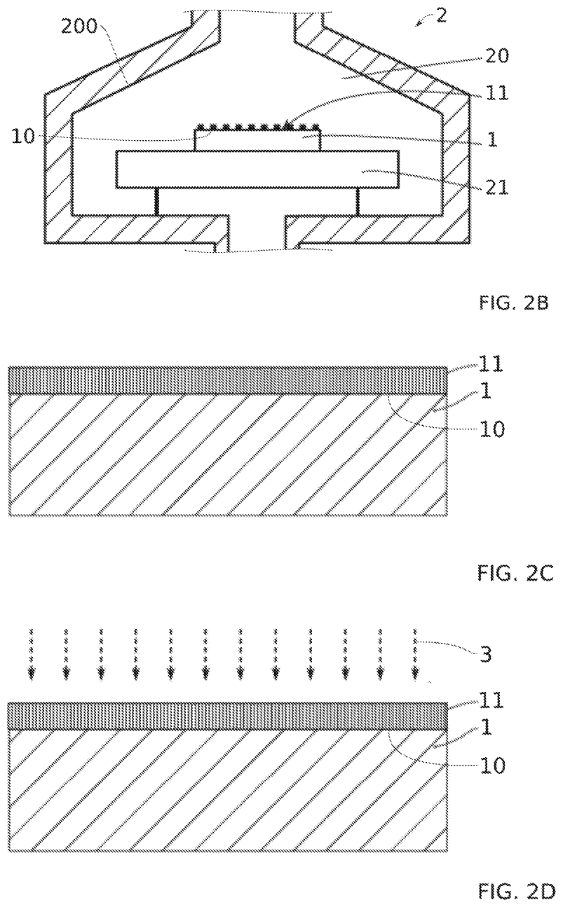

For the activation of the exposed layer 10, two examples of embodiments of the method are described relative to FIGS. 2A to 2D, then 3A to 3C.

According to the first example illustrated by FIGS. 2A to 2D, the structure 1 is provided inside the reaction chamber 20 of a reactor 2, for example a plasma reactor. The structure 1 can more specifically be placed on the plate or sample holder 21 in the reaction chamber 20, as for example illustrated by FIG. 2A.

The structure 1 being placed in the reaction chamber 20, the method can comprise the deposition of the layer CₓH_{y}F_{z} 11, as for example illustrated by FIGS. 2A and 2B. The layer CₓH_{y}F_{z} 11 is thus deposited on, and preferably directly in contact with, the exposed layer 10, as illustrated, for example, by FIG. 2C. It is noted that during this deposition of the layer CₓH_{y}F_{z} 11, the material CₓH_{y}F_{z} can further be deposited on the walls 200 of the reaction chamber 20.

The method then comprises the treatment of the layer CₓH_{y}F_{z} 11 by the oxygen-and/or nitrogen-based activation plasma 3, as for example illustrated by FIG. 2D. The layer CₓH_{y}F_{z} 11 on the exposed layer 10 is thus at least partially consumed. The activation plasma reacts with the material CₓH_{y}F_{z}. During this reaction, carbon is removed in the form of gas, for example in the form of chemical formula CO, CO₂, CN according to the chemistry of the plasma. The fluorine contained in the layer CₓH_{y}F_{z} 11 reacts with the exposed layer 10, which induces its activation. Advantageously, the treatment by the activation plasma 3 makes it possible to remove the carbon element which could impact the bonding energy and/or the properties of the resulting microelectronic device. For this, the parameters of the plasma can, for example, be adjusted, such as the power of the source, the pressure in the reaction chamber 20, the duration of the plasma and/or the content in the plasma of species which react with carbon to form volatile products.

Preferably, the treatment by the activation plasma 3 is performed so as to consume at least 90% and preferably all the carbon atoms of the layer CₓH_{y}F_{z} 11. According to an example, the layer CₓH_{y}F_{z} 11 is at least at 90% and preferably totally consumed. Thus, there no longer remains material CₓH_{y}F_{z} 11 during a subsequent assembly with the exposed layer 40 of another substrate 4, for example illustrated by FIG. 5. The bonding and/or the properties of the resulting microelectronic device are thus further improved. The quality of the interface between the exposed layer 10 and the exposed layer 40 after assembly is improved.

The properties, for example, the remaining quantity of carbon atoms, of the exposed layer 10 after treatment by the activation plasma 3 can be analysed by a characterisation of the exposed layer 10, for example by X-ray photoelectron spectrometry (XPS). The exposed layer 10, once activated, has in particular on the surface, bonds with fluorine atoms, and preferably further bonds with hydrogen atoms. As an example, after treatment by an O₂-based activation plasma 3, the silicon-based exposed layer 10 can have a surface of SiOₓF_{y}H_{z} type in the case of a silicon-on-insulator (SOI) substrate. According to another example, after treatment by an N₂-based activation plasma 3, the silicon-based exposed layer 10 can have a SiOₓF_{y}H_{z}N_{w}-type surface in the case of a silicon-on-insulator substrate. It is noted that hydrogen is not detected in XPS.

According to this example, the deposition of the layer CₓH_{y}F_{z} 11 and the treatment by the activation plasma 3 can be performed in the reaction chamber 20 between the deposition of the layer CₓH_{y}F_{z} 11 and the treatment by the activation plasma 3. The presence of impurity on the layer CₓH_{y}F_{z} 11 and in the exposed layer 10 is thus better controlled, and preferably avoided. Alternatively, the deposition of the layer CₓH_{y}F_{z} 11 and the treatment by the activation plasma 3 can be performed in distinct reaction chambers 20.

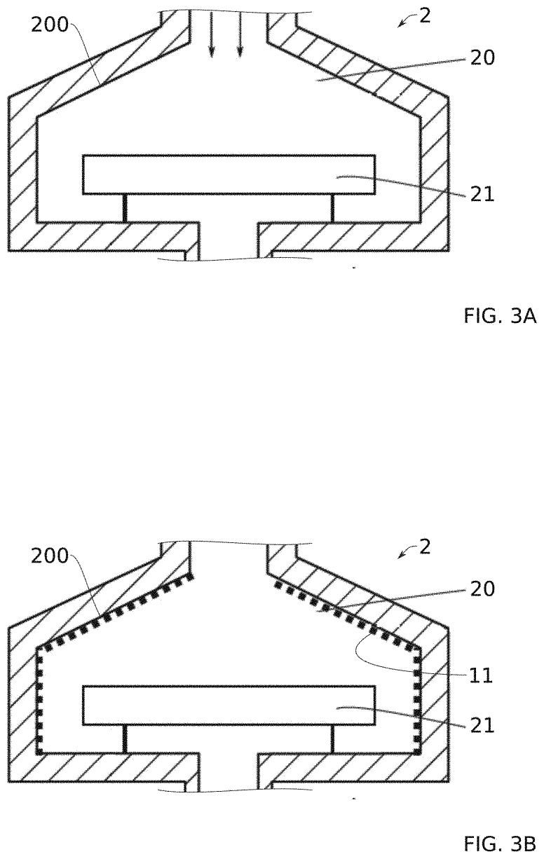

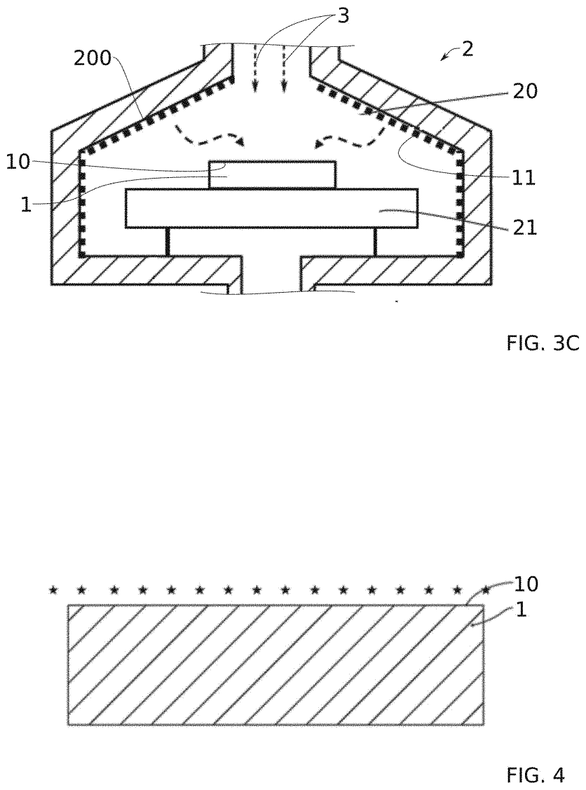

According to the second example illustrated by FIGS. 3A to 3D, the method can comprise the deposition of the layer CₓH_{y}F_{z} 11, while the structure is not provided inside the reaction chamber 20 of the reactor 2, for example a plasma reactor, as for example illustrated by FIGS. 3A and 3B. The deposition is thus configured such that the layer CₓH_{y}F_{z} 11 is deposited on the walls 200 of the reaction chamber 20, as illustrated, for example, by FIG. 3B.

The method then comprises the provision of the structure 1 inside the reaction chamber 20, for example on the sample holder 21. The treatment by the oxygen- and/or nitrogen-based activation plasma 3 is configured to consume at least partially the layer CₓH_{y}F_{z} 11, as for example illustrated by FIG. 3C. The activation plasma reacts with the material CₓH_{y}F_{z}. During this reaction, carbon is removed in the form of gas, for example in the form of CO, CO₂, CN, according to the chemistry of the plasma. The fluorine contained in the layer CₓH_{y}F_{z} 11 on the walls 200, under the impact of the activation plasma 3, reacts with the exposed layer 10 disposed in the chamber 200, which induces the activation of the exposed layer 10. Advantageously, the treatment by the activation plasma 3 avoids the incorporation of carbon on the exposed layer 10, which could impact the bonding energy and/or the properties of the resulting microelectronic device. In particular, it will be ensured that the energy from the activation plasma does not enable the carbon species to be introduced in the exposed layer 10 that is sought to be activated.

Preferably, the treatment by the activation plasma 3 is performed so as to consume at least 90% and preferably all the carbon atoms of the layer CₓH_{y}F_{z} 11. According to an example, the layer CₓH_{y}F_{z} 11 is at least at 90% and preferably, totally consumed. According to an example, the layer CₓH_{y}F_{z} 11 is totally consumed such that there no longer remains material CₓH_{y}F_{z} on the walls 200. To verify this, it is, for example, possible to sample a sample on the walls 200 and to perform an XPS analysis on this sample to verify the presence or not of material CₓH_{y}F_{z}. It is further possible to produce an activation plasma on a substrate, on which a carbon layer has not been deposited beforehand, and follow a carbon-type line, for example that of carbon monoxide CO, during the plasma and/or perform an XPS analysis on the substrate.

Whether the layer CₓH_{y}F_{z} deposited on the exposed layer 10 and/or on the walls 200 of the reaction chamber 20, the etching of the exposed layer 10 is limited, and preferably avoided, while applying a fluorine source in the proximity of the exposed layer 10, for the activation of the exposed layer during the treatment by the activation plasma 3.

At least one from among the deposition of the layer CₓH_{y}F_{z} 11 and the treatment by the activation plasma 3 can be repeated several times. Several arrangements of steps can, for example, be provided. It can be provided that the deposition of the layer CₓH_{y}F_{z} 11, then the provision of the structure 1 in the reaction chamber 20, then the treatment by the activation plasma are repeated several times. It can be provided that, following the provision of the structure in the reaction chamber 20, the deposition of the layer CₓH_{y}F_{z} 11 then the treatment by the activation plasma are repeated several times. Further, examples can be provided, wherein the two examples of embodiments of the method presented above are combined.

The deposition of the layer CₓH_{y}F_{z} 11 is now described in more detail. The deposition of the layer CₓH_{y}F_{z} 11 can be a chemical vapour deposition (CVD). The deposition of the layer CₓH_{y}F_{z} 11 can be a plasma-enhanced chemical vapour deposition (PE-CVD). A plasma-enhanced deposition enables a better conformity and/or uniformity of the carbon layer. A plasma-enhanced deposition in a deposition reactor is further performed, generally at a higher pressure than in an etching reactor. The risk of etching of the exposed layer in the first seconds of the plasma is thus minimised.

According to an example, the deposition of the layer CₓH_{y}F_{z} 11 is a chemical deposition from at least one gaseous precursor. The at least one gaseous precursor can comprise carbon, hydrogen and fluorine elements. The at least one gaseous precursor can be of chemical formula CᵤHᵥF_{w}, u, v and w being positive integers, at least u and w being non-zero. According to an example u, v, and w are non-zero. The precursor can have a formula CᵤHᵥF_{w} or CᵤF_{w} when v=0, excluding CF₄. The precursor is different from CF₄ which does not make it possible solely to deposit a fluorinated layer 11 on the surface of the exposed layer. According to an example, during the deposition of injected gases comprise CF₄ in association with the at least one gaseous precursor. According to an alternative example, during the deposition, the injected gases do not comprise CF₄. For example, the at least one gaseous precursor is chosen from among compounds of formula CH₂F₂ and CHF₃, CH₃F, C₄F₈ and C₄F₆.

According to an example, the at least one gaseous precursor can be of chemical formula CᵤF_{w}, u and w being non-zero positive integers, with a hydrogen-based precursor, for example H₂.

The deposition of the layer CₓH_{y}F_{z} 11 can comprise an injection of the gaseous precursor(s), optionally mixed with other precursors and/or one or more neutral gases. According to an example, at least one precursor of chemical formula CᵤHᵥF_{w} can be solely injected, without precursor of chemical formula other than CᵤHᵥF_{w}. According to an alternative example, a precursor of chemical formula CᵤHᵥF_{w} can be injected with the addition of at least one precursor of chemical formula other than CᵤHᵥF_{w} or CᵤF_{w} excluding CF₄, for example a CF₄ precursor, or an oxygen- and/or nitrogen-based precursor, such as O₂ or N₂. These precursors make it possible to limit polymerisation on the surfaces of the precursors CᵤHᵥF_{w} and to slow down the deposition speed of the layer 11. A better control of the deposition of the layer 11 is thus obtained. Preferably, to further improve this control of the deposition, the quantity of precursor of chemical formula CᵤHᵥF_{w} or CᵤF_{w} excluding CF₄ injected, for example the flow rate, is substantially 4 and preferably 5 times greater than or equal to the quantity of the other precursor(s), for example at their flow rate.

According to an example, the flow rate of injected precursor(s) is substantially between 5 and 50 sccm, preferably between 5 and 40 sccm (standard cubic centimetres per minute, and commonly used in the field for measuring the flow rate of a gas). According to an example, the flow rate of injected precursor(s) of chemical formula CᵤHᵥF_{w} is substantially less than or equal to 40 sccm and/or substantially greater than or equal to 20 sccm. Preferably, the flow rate of injected precursor(s) of chemical formula CᵤHᵥF_{w} or CᵤF_{w} excluding CF₄ is substantially equal to 35 sccm. The pressure can be substantially equal to 10 mT. The flow rates and pressure are in particular chosen in order to control the flow rate speed and to obtain a good uniformity of the deposited layer 11.

The temperature in the reaction chamber, preferably the temperature of the substrate, during the deposition of the layer 11, can be between substantially 10° C. and 250° C., preferably less than or equal to 100° C., and preferably substantially between 20° C. and 80° C. The temperature in the reaction chamber can be the temperature of the walls of the chamber 20 and/or the temperature of the sample holder 21. The power of the plasma source can be between 200 W and 3000 W during the deposition of the layer 11.

According to an example, during the deposition of the layer 11, a CH₂F₂ precursor is injected at a flow rate substantially equal to 35 sccm, in addition to CF₄ at a flow rate of 5 sccm, at a pressure of 10 mTorr and an RF power of the plasma Pₛ₋ₚₗₐₛₘₐ of 800 W.

The deposition of the layer CₓH_{y}F_{z} 11 can be configured such that the layer CₓH_{y}F_{z} 11 has a thickness substantially greater than or equal to 1 nm, preferably 2 nm. During the development of the invention, it has been highlighted that this thickness would enable a sufficient activation for the subsequent bonding. The deposition of the layer CₓH_{y}F_{z} 11 can be configured such that the layer CₓH_{y}F_{z} 11 has a thickness substantially less than or equal to 10 nm, preferably 5 nm. The time necessary for the deposition of the layer is thus limited, while making it possible to obtain a sufficient activation for the subsequent bonding. The deposition of the layer CₓH_{y}F_{z} 11 can be configured such that the layer CₓH_{y}F_{z} 11 has a thickness substantially between 1 nm and 10 nm, and preferably between 2 nm and 5 nm.

The treatment by the activation plasma 3 is now described in more detail. The treatment by the activation plasma 3 can comprise an injection of at least one gas into the reaction chamber and a formation of the activation plasma 3 from the gas. The activation plasma 3 is based on at least one from among oxygen and nitrogen to react with the layer CₓH_{y}F_{z} 11. For example, the at least one injected gas comprises dioxygen and/or dinitrogen. The gas can be injected in a mixture with one or more neutral gases, for example helium or argon. According to an example, the flow rate of injected gas(es) is substantially between 5 and 200 sccm. The pressure in the reaction chamber can be substantially between 30 mTorr and 200 mTorr (with 1 Torr equal to around 133.322 pascals (Pa) in the International System of Units). The temperature in the reaction chamber, preferably the temperature of the substrate, during the activation plasma, can be substantially between 10° C. and 250° C. The power of the plasma source can be between 200 W and 3000 W during the activation plasma.

The treatment by the activation plasma 3 can be continuous. According to an alternative example, the treatment by the activation plasma can be pulsed. During the formation of the continuous or pulsed plasma, the gases are preferably injected continuously.

During the treatment by the pulsed activation plasma 3, the pulsed plasma can be obtained by making the plasma source and/or the polarisation V_{bias-substrat} applied to the structure operate by intermittence, preferably periodically. The application of the plasma on the structure is thus split over time.

According to an example, the self-polarisation voltage V_{bias-substrat} applied to the structure is pulsed, i.e. that the application of the polarisation voltage comprises a succession, alternatively of application and of lesser application of the polarisation voltage to the structure. According to an example, the application of the polarisation voltage comprises a succession, alternatively of application and of non-application of the polarisation voltage to the structure. According to an example, alternating, a polarisation voltage V_{bias-substrat}1 and a polarisation voltage V_{bias-substrat}2 are applied to the structure successively, with |V_{bias-substrat}2|<|V_{bias-substrat}1|, and preferably |V_{bias-substrat}1|≥5*|V_{bias-substrat}2| and more preferably |V_{bias-substrat}1|≥10*|V_{bias-substrat}2|. Preferably, successively alternating, a self-polarisation voltage V_{bias-substrat}1 is applied to the structure and no self-polarisation voltage is applied to the structure. When no self-polarisation voltage V_{bias-substrat}2 is voluntarily applied to the structure 1, it is noted that a residual polarisation voltage can be applied to the structure, in particular due to a sheath phenomenon in the plasma. |V_{bias-substrat}2| can thus be substantially equal to 20V, and more specifically substantially equal to 15V. The fact that the plasma treatment 3 is pulsed enables a larger parameter window to minimise the etching of the exposed layer, while enabling its activation.

As said above, the treatment by the activation plasma 3 comprises an injection of at least one gas in the reaction chamber 20 and a formation of a plasma from this gas. The treatment can further comprise several cycles, each cycle comprising an alternance of a draining and of the formation of a plasma, and this cycle being repeated several times during the treatment. In this case also, the application of the plasma on the substrate is split over time. This treatment is therefore referenced by the term of “cyclical plasma”, opposed to a treatment where the cleaning is performed by the application of a plasma continuously.

The treatment by the activation plasma can comprise at least one and preferably several cycles. Each cycle comprises at least two, and preferably three, main steps. Each cycle can comprise a step, usually qualified as draining. The draining has the function of discharging the gaseous species possibly present in the reaction chamber 20, for example of discharging the reactional subproducts following the treatment by plasma. According to an example, in the cycle, the draining is performed before the formation of the plasma. Thus, the composition of the plasma formed is better controlled, to ensure the quality of the plasma is obtained. This draining generally consists of injecting a neutral gas such as argon or helium into the reaction chamber 20.

During the formation of the plasma 3, a self-polarisation voltage, preferably non-zero, is applied. The self-polarisation voltage can be applied to the reaction chamber 20. Thus, the energy of the ions of the activation plasma can be modulated to improve the effectiveness of the ion bombardment on the layer CₓH_{y}F_{z} 11 and therefore the activation of the exposed layer, while limiting the etching of the exposed layer 10. For this, the self-polarisation voltage can be strictly less than 0. The absolute value of the self-polarisation voltage can be substantially greater than or equal to 100V, preferably 200V. The absolute value of the self-polarisation voltage can be substantially less than or equal to 500V.

The treatment by the activation plasma 3 can be performed in a reaction chamber 20 of a reactive ion etching reactor (commonly abbreviated to RIE, comprising CCP and ICP reactors detailed below.

The treatment by the activation plasma 3 can, according to a first example, be performed in a reaction chamber 20 of a capacitively coupled plasma (CCP) reactor 20. In a capacitively coupled plasma reactor, the self-polarisation voltage is not separable from the RF power Pₛ₋ₚₗₐₛₘₐ supplied to create the plasma. In the case of a CCP-type plasma reactor, the self-polarisation voltage is necessarily non-zero. The plasmas thus produced are capable of depositing a layer CₓH_{y}F_{z} 11 during the deposition step, and producing the activation plasma 3.

The treatment by the activation plasma 3 can, according to a second example, be performed in a reaction chamber 20 of an inductively coupled plasma (ICP) reactor 2. In an inductively coupled plasma reactor, the self-polarisation voltage is generated by the RF power applied to the sample holder 21. It therefore corresponds to a polarisation voltage applied to the structure or equivalently, to the substrate V_{bias-substrat}. The RF power applied to the source 25 of the reactor plasma itself determines the ion density of the plasma. The advantage of an ICP-type plasma reactor is therefore being able to separate the ion bombardment on the substrate from the density of the plasma. An inductively coupled plasma will be preferred, which makes it possible to independently control the V_{bias-substrat} with respect to the RF power Pₛ₋ₚₗₐₛₘₐ of the plasma source 25 for a better control of the self-polarisation voltage, by separation of the voltage applied to the substrate and the RF power of the plasma Pₛ₋ₚₗₐₛₘₐ.

Thus, the ion bombardment on the layer CₓH_{y}F_{z} 11 and the etching of the exposed layer 10 can be even better controlled and preferably minimised. Consequently, the subsequent bonding will be improved. Furthermore, the quality of the interface between the exposed layer 10 and the exposed layer 40 after assembly of the structure 1 and of the substrate 4 is improved.

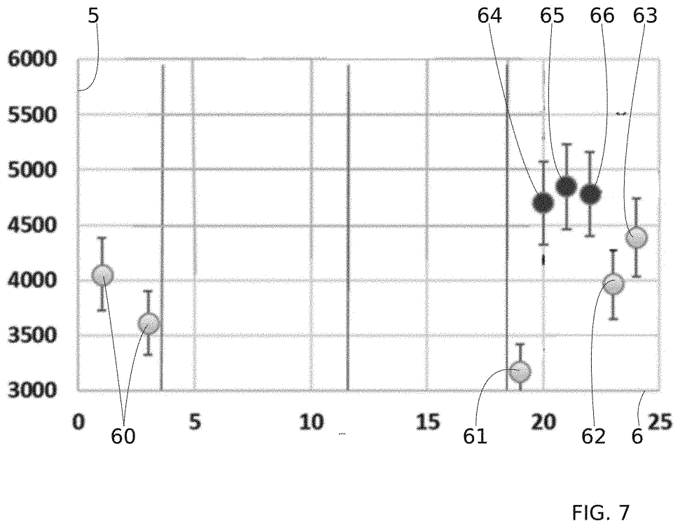

In practice, as for example illustrated by FIG. 6, the reaction chamber 20 comprises a reception plate 21 of the substrate, or also sample holder. According to an example, the polarisation voltage V_{bias-substrat} is applied to the plate 21. Preferably, the polarisation voltage V_{bias-substrat} is applied only to the plate 21. According to this example, the plate 21 is electrically conductive and the polarisation voltage V_{bias-substrat} is applied to this plate 21 by a voltage regulation device 26 to be transmitted to the structure 1. The voltage regulation device 26 is, for example, configured to apply an RF power to the sample holder.

According to an example, the absolute value of the polarisation voltage |V_{bias-substrat}| applied is substantially less than or equal to 500V. The absolute value of the polarisation voltage |V_{bias-substrat}| applied can be substantially greater than or equal to 50V. It will be noted that this polarisation voltage is lower than the polarisation voltages usually used to perform plasma implantations in a CCP reactor. Furthermore, this method is preferably implemented in a deposition plasma reactor. Etching plasma reactors are not configured to apply as low polarisation voltages to the substrate.

The polarisation voltage V_{bias-substrat} can be applied for at least 70% of the formation duration of the plasma, preferably at least 90%, and even more preferably for the whole formation duration of the plasma. According to an example, the polarisation voltage V_{bias-substrat} is applied only during the treatment by the activation plasma 3. According to an example, the polarisation voltage V_{bias-substrat} is applied only during the formation of the plasma, during the treatment by the activation plasma 3.

An ICP reactor is now described as an example in reference to FIG. 6. Relatively conventionally, the reactor 2 comprises a gas inlet 22 making it possible to inject inside the chamber 20, the gases intended to form the chemistry of the plasma, as well as the gases intended for the draining phases. The plasma source 25 is, according to an example, an induction coupling device 25, a coil of which is illustrated in FIG. 6, which enables the formation of the plasma. The plasma source 25 can be radiofrequency (RF-ICP in FIG. 6). The reactor 2 also comprises an isolation valve 23 of the reaction chamber 20. The reactor 20 also comprises a pump 24 configured to control the pressure inside the reaction chamber 20 synergically with the flow rate of the injected gases, and to extract the species present in the reaction chamber 20.

Advantageously, this reactor 2 comprises a polarisation device 26 configured to enable the application of the polarisation voltage V_{bias-substrat} to the plate 21, for example via a radiofrequency power generator. This voltage can ultimately be applied to the structure 1, at the very least on its face rotated facing the plate 21, whether this face is electrically conductive or not. This polarisation device 26 is preferably distinct from the plasma source 25. This polarisation device 26 can comprise a control device 260 configured to apply an alternating voltage on the plate 21.

According to this example, the polarisation device 26 and the plasma source 25 are configured so as to be able to adjust the polarisation voltage V_{bias-substrat} applied to the plate 21 independently from the RF power Pₛ₋ₚₗₐₛₘₐ of the plasma source 25. V_{bias-substrat} and Pₛ₋ₚₗₐₛₘₐ can be independent. V_{bias-substrat} and Pₛ₋ₚₗₐₛₘₐ can be controlled independently.

According to an alternative example, during the formation of the activation plasma 3, no voltage V_{bias-substrat} is applied to the substrate.

Particular examples of embodiments and associated bonding energy.

FIG. 7 illustrates the bonding energy 5 (in mJ·m⁻²) measured on assemblies. The bonding energy is measured by measuring the quantity of energy necessary to separate the two substrates forming the assembly. These assemblies are assemblies 6 of two substrates by direct bonding, one of the substrates being:
60 a substrate having an exposed layer activated by an O₂ activation plasma in a CCP reactor, without prior deposition of a carbon layer,
61 a substrate having an exposed layer activated by an O₂ activation plasma in an ICP reactor, without prior deposition of a carbon layer,
62 a substrate having an exposed layer activated by a deposition of a fluorinated layer from CH₂F₂ and CF₄ or O₂ or N₂ gas on the walls of the reactor, then an O₂ activation plasma in a CCP reactor,
63 a substrate having an exposed layer activated by a deposition of a fluorinated layer from CH₂F₂ and CF₄ precursor on the walls of the reactor, then an N₂ activation plasma in a reactive etching reactor (commonly abbreviated as RIE, for reactive-ion-etching),
64 a substrate having an exposed layer activated by a deposition of a layer CₓH_{y}F_{z} on the exposed layer, then an O₂ activation plasma in an RIE reactor, according to an example of an embodiment of the method,
65 a substrate having an exposed layer activated by a deposition of a layer CₓH_{y}F_{z} on the exposed layer, then an N₂ activation plasma in an RIE reactor, according to an example of an embodiment of the method,
66 a substrate having an exposed layer activated by a deposition of a layer CₓH_{y}F_{z} on the walls of the reactor, then an O₂ activation plasma in an RIE reactor, according to an example of an embodiment of the method.

In these examples, the experimental parameters are such as described above.

The assemblies obtained with the activation method according to the activation method according to the examples of embodiments below make it possible to obtain a bonding energy greater than those obtained by the current solutions. The deposition of a layer CₓH_{y}F_{z} prior to a treatment by an activation plasma makes it possible to increase the activation of the exposed layer and therefore the bonding energy of the resulting assembly. For examples 64 to 66, an opening of the assembly outside of the interface has even been observed during bonding energy measurements, i.e. that the substrates are separated by breaking one of the substrates outside of the interface formed by their exposed layers. The bonding energy obtained in these examples is therefore greater than the energy of the material constituting the substrate.

In view of the description above, it appears clearly that the invention proposes a method improving the direct bonding on a substrate, and in particular making it possible to limit the etching of the exposed layer.

The invention is not limited to the embodiments described above, and extends to all the embodiments covered by the invention. The present invention is not limited to the examples described above. Many other variants of embodiments are possible, for example by combining features described above, without moving away from the scope of the invention. Furthermore, the features described relative to an aspect of the invention can be combined with another aspect of the invention.

The invention also extends to the embodiments, wherein the structure is deposited on a silicon-based substrate.

Moreover, in the examples described above, the structure is a layer. However, all the examples, features, steps and technical advantages mentioned above in reference to a structure forming a layer are applicable to a structure not forming a layer, but forming a punctual structure, for example a three-dimensional raised part. The structure can be a nanostructure or comprise a plurality of nanostructures.

1. A method for activating an exposed layer of a structure comprising:
a provision of a structure comprising an exposed layer in a reactor, the reactor comprising a reaction chamber inside which the structure is disposed,
before or after the provision of the structure, a deposition in the reaction chamber of a layer based on a material of chemical formula CₓH_{y}F_{z}, x, y and z being positive integers, at least x and z being non-zero,
a treatment, in the presence of the structure, of the layer based on a material of chemical formula CₓH_{y}F_{z} by an activation plasma based on at least one from among oxygen and nitrogen, the treatment by the activation plasma being configured to consume at least partially the layer based on the material of chemical formula CₓH_{y}F_{z} so as to activate the exposed of the structure.

2. The method according to claim 1, wherein the provision of the structure is made before the deposition in the reaction chamber, the layer based on a material of chemical formula CₓH_{y}F_{z} thus being deposited on the exposed layer of the structure.

3. The method according to the preceding claim 2, wherein the deposition of the layer based on a material of chemical formula CₓH_{y}F_{z} and the treatment by the activation plasma are performed in the same reaction chamber.

4. The method according to claim 1, wherein the provision of the structure is made after the deposition of the layer based on a material of chemical formula CₓH_{y}F_{z} in the reaction chamber and before the treatment by the activation plasma, the layer based on a material of chemical formula CₓH_{y}F_{z} thus being deposited on walls of the reaction chamber, and the deposition of the layer based on a material of chemical formula CₓH_{y}F_{z} and the treatment by the activation plasma being performed in the same reaction chamber.

5. The method according to claim 1, wherein the treatment by the activation plasma is performed so as to consume at least 90% and preferably all of the carbon atoms of the deposited layer based on a material of chemical formula CₓH_{y}F_{z}.

6. The method according to claim 1, wherein the treatment by the activation plasma comprises the application in the reaction chamber of a voltage, called self-polarisation voltage, wherein an absolute value of the self-polarisation voltage is between 100V and 500V.

7. The method according to claim 1, wherein the treatment by the activation plasma is performed in a reaction chamber of a capacitively coupled plasma reactor.

8. The method according to claim 1, wherein the treatment by the activation plasma is performed in a reaction chamber of an inductively coupled plasma reactor.

9. The method according to claim 8, wherein during the treatment by the activation plasma, a polarisation voltage V_{bias-substrat} is applied to the structure.

10. The method according to claim 1, wherein the deposition of the layer based on a material of chemical formula CₓH_{y}F_{z} is a chemical deposition from at least one gaseous precursor.

11. The method according to claim 10, wherein the at least one gaseous precursor comprises at least carbon, and fluorine elements, the at least one gaseous precursor being different from CF₄, the at least one gaseous precursor preferably being of chemical formula CᵤHᵥF_{w}, u, v and w being positive integers, at least u and w being non-zero and excluding CF₄, for example the at least one gaseous precursor is chosen from among compounds of formula CH₂F₂ and CHF₃, CH₃F, C₄F₆ and C₄F₈.

12. The method according to claim 1, wherein the treatment by the activation plasma comprises an injection of at least one gas into a reaction chamber of a plasma reactor and a formation of the activation plasma from said gas in the reaction chamber, the at least one gas comprising dioxygen, dinitrogen, helium or their mixture.

13. The method according to claim 1, wherein the exposed layer is silicon-based, for example the exposed layer is based on or made of a silicon oxide, a silicon nitride or silicon.

14. The method according to claim 1, comprising, after the treatment by the activation plasma, the assembly by direct bonding of the exposed layer of the structure with an exposed layer of a distinct substrate.

15. The method according to claim 1, wherein at least one from among the deposition of the layer based on a material of chemical formula CₓH_{y}F_{z} and the treatment by the activation plasma can be repeated several times.

16. A method for bonding an exposed layer of a structure with an exposed layer of a distinct substrate, the method comprising:
the activation of the exposed layer of the structure by implementing the method according to claim 1,
the contact of the exposed layer of the structure with the exposed layer of the distinct substrate.
